(19) United States
(12) Patent Application Publication
(10) Pub. No.: US 2026/0191322 A1
(43) Pub. Date: Jul. 9, 2026

(54) ADAPTER HANDSET AND METHOD OF OPERATION

(71) Applicant: Wellnomics Limited, Sydenham, Christchurch (NZ)

(72) Inventors: Marcus Neary Clyne, Halswell, Christchurch (NZ); James Whitmore, Hawarden (NZ)

(21) Appl. No.: 19/128,349

(22) PCT Filed: Nov. 8, 2023
(86) PCT No.: PCT/NZ2023/050125

§ 371 Date: May 8, 2025

(30) Foreign Application Priority Data
Nov. 8, 2022 (NZ) 794243

(51) Int. Cl. A47B 21/02; G05B 19/042; G06F 1/26

(52) U.S. Cl. CPC A47B 21/02; G05B 19/0423; G06F 1/266; A47B 2200/0057; A47B 2200/0061; A47B 2200/0062

(57) ABSTRACT

An adapter handset is provided for electrically interfacing with a desk controller of an electrically powered sit-stand desk. The adapter handset includes a multi-pin handset connector and a processor. The desk controller includes a multi-pin desk controller connector. The adapter handset is connected to the desk controller via conductive connections between the pins of the multi-pin desk controller connector and corresponding pins of the multi-pin handset connector. Voltage measurements of the connected pins are made and compared with records in a database of Desk Controller Connector Pinout Fingerprints (DCCPFs) that match known desk controllers to find the correct Desk Controller Connector Pinout Fingerprint (DCCPF). The adapter handset processor then automatically reconfigures the Adapter Handset Connector Pinout Fingerprint (AHCPF) to match the found DCCPF.

### CROSS REFERENCE TO RELATED APPLICATIONS

This present application is a § 371 national stage of International Application PCT/NZ2023/050125, filed Nov. 8, 2023, which claims priority benefit of New Zealand Pat. Application Ser. No. 794243, filed Nov. 8, 2022, both of which are hereby incorporated herein by reference in their entireties.

### FIELD OF THE DISCLOSURE

The present disclosure relates to an adapter handset and method of operation for controlling disparate motor controllers. In particular, the present disclosure relates to an adapter handset for universal control of disparate controllers used for controlling motors on sit-stand desks and the like.

### BACKGROUND

The importance of ergonomics in workplace furniture and workstations has seen widespread adoption of variable height, electrically-powered ‘sit-stand’ desks or workstations. The benefits of such desks/workstations includes:
allowing simple, tool-free and immediate hight adjustment optimised for each individual without need for manual readjustment, or footrests.
facilitating flexible or unassigned seating (also known as ‘hot-desking’) without compromising ergonomics for each user;
offsetting the harmful impacts of prolonged sitting, by allowing standing desk usage and simple alternation between the two positions.

The sit-stand workstation market is supplied by a relatively large number of manufacturing companies, who also produce a wide range of other furniture and office fit-out equipment. Electrically powered desks are a relatively recent development in this mature market and has thus led these companies to outsourcing of the electrical drive/control component manufacture. The overwhelming majority of current sit-stand workstations include electronic componentry from less than 10 companies worldwide.

The electronic componentry of a typical sit-stand workstation desk comprises at least one:
motor,
linear actuator such as a worm-drive mechanism,
electronic controller, controlling the motor (and typically includes a mains power connection), and
handset, operated by the user for desk height adjustment as well as settings display, historical data storage, pre-sets, and collision/overload protection.

Despite the modest number of parties involved in this specialised area of the industry, these competitors have little incentive for standardisation of componentry or collaboration.

Moreover, the electrical componentry supplied is typically customised to the specific desk manufacturers requirements, further preventing interoperability.

### SUMMARY

Reference herein is made to the present disclosure as relating to a sit-stand desk controller, although this should not be seen as limiting.

Interconnection and interoperability are a fundamental tenet of a ‘smart office’, whereby the interaction between the users, their workstations and the office environment generally may be monitored and optimised. A sit-stand workstation is a natural cornerstone component for smart offices and, due to the fact that it requires a continuous power supply to operate the desk, it provides a means to also supply power for performing monitored feedback on the frequency and nature of sit-stand workstation usage.

It will be appreciated that monitoring numerous other environmental and performance metrics may be readily provided by sensors either incorporated in, or interfacing with, the sit-stand desk control system. It will also be appreciated that businesses seeking to refurbish or expand its office space and/or its smart-office capabilities would prefer:
to avoid retrofitting new sensors or controllers to existing desks;
flexibility for sourcing new equipment without being locked to a single, existing supplier;
interoperability via recognised, non-proprietary connection standards/protocols—e.g. Bluetooth, Wi-Fi, NFC, etc.

Unlike other prevalent office furniture, the pre-existence of electronics and electrical power in electric sit-stand desks naturally lends itself to the incorporation of such sensors.

Thus, an electrical controller is disclosed that is capable of interfacing with a plurality of sit-stand desks and able to provide a standard interface, irrespective of the desk model or manufacturer.

As discussed above, a hinderance to the implementation of smart office capabilities in office environments with sit-stand desks is the inability of the communication between products from different manufacturers. Moreover, neither the sit-stand desk manufacturers, nor their electrical drive component manufacturers are strongly incentivised to develop such additional, niche capacities outside of their core business focus.

The cost distribution of the electrical componentry of a typical sit-stand desk spans between the electrical drive as the most expensive, followed by the electronic controller, to the user-operated handset connected to the controller being the cheapest. Axiomatically, it is thus desirable to provide customers with a replacement handset, rather than the need for costly retrofitting of the significantly more expensive electrical drives/controllers.

In conventional offices, (i.e., non-smart offices), sit-stand workstations are simply adjusted by the user according to their ergonomics and/or their desire to alternate between sitting and standing. User control of such activities may be easily accomplished by a desktop handset, with a simple raise/lower control. More sophisticated/featured handsets may include a numerical height display and multiple configurable pre-set heights, also useful for hot-desking workstations used by multiple users. Safety features such as an auto-stop when encountering unexpected load fluctuations (e.g., pressing on a user's leg) do not require dedicated user controls or displays.

Even if a given collection of such desks provided the inputs (via a wired or wireless communications connection means) for some form of centralised, user-data collection capacity, it would be incompatible with sit-stands desks from different manufacturers. Due to the above-referenced disincentive to produce products interoperable with other manufacturers, it follows that the manufacturers do not overtly publish details of the interconnections between controllers and handsets, nor adhere to recognised connection protocols or standards.

Thus, an adapter handset is disclosed that is capable of interfacing with a plurality of different sit-stand desk controllers.

Sit-stand workstations are bulky and heavy typically being at least 1800 mm×800 mm with the metal frame, legs and motors typically weighing 30-40 kg. They are typically delivered in kitset form due to this bulk and then assembled onsite, normally in the location they will be used. The kitset contents for each desk is customizable, with the customer being able to specify the parts they wish included, the costs being adjusted accordingly

Part of the costs of installing the sit-stand workstation include the mounting and plugging in the handset on the edge of the desk. The costs of the handset and installation can be a significant proportion of the cost of the desk.

Thus, an adaptor handset is disclosed to both work in parallel with an existing handset as an aftermarket addition, or entirely as a complete replacement for the existing handset of any manufacturer that could be installed as part of the normal initial assembly.

Moreover, an adapter handset is disclosed that is capable of auto-identification of a given controller and optionally thereafter, self-configurable to be powered by, and interface with, the controller.

To facilitate smart office capabilities, it would also be desirable to integrate or connect with additional sensors, capable of providing sensing data on additional example metrics such as temperature, humidity, ambient noise, ambient light measurement, desk orientation, user presence detection, automated control and measurement of sit-stand workstation height, automated asset location-detection and utilisation tracking, and a generalized user interface (UI) to accommodate supplementary features e.g. workstation booking/availability, in addition to basic workstation desk height data/status.

Thus, a standardised, open communication interface, or ‘platform’, is disclosed which is agnostic of the manufacturer/desk model/controller and may be attractive to both potential software/hardware developers and customers.

Moreover, a standardised, open communication interface, or ‘platform’ standard interface to all the above features that is independent of controller & desk model or manufacturer would also be desirable such as to customers (including individual users, office managers and employers/owners).

It is an object of the present disclosure to address the foregoing problems or at least to provide the public with a useful choice.

All references, including any patents or patent applications cited in this specification are hereby incorporated by reference. No admission is made that any reference constitutes prior art. The discussion of the references states what their authors assert, and the applicants reserve the right to challenge the accuracy and pertinency of the cited documents. It will be clearly understood that, although a number of prior art publications are referred to herein, this reference does not constitute an admission that any of these documents form part of the common general knowledge in the art, in New Zealand or in any other country.

It is acknowledged that the term ‘comprise’ may, under varying jurisdictions, be attributed with either an exclusive or an inclusive meaning. For the purpose of this specification, and unless otherwise noted, the term ‘comprise’ shall have an inclusive meaning—i.e. that it will be taken to mean an inclusion of not only the listed components it directly references, but also other non-specified components or elements. This rationale will also be used when the term ‘comprised’ or ‘comprising’ is used in relation to one or more steps in a method or process. Further aspects and advantages of the present disclosure will become apparent from the ensuing description which is given by way of example only.

Reference throughout this specification to the singular should be interpreted to include the plural and vice versa unless specifically stated otherwise.

As used herein, the term ‘workstation’ includes, but is not limited to, a desk, chair, computer stand/mount, shelving, draws and the like.

As used herein, the term ‘sit-stand desk’ includes any electrically powered height-adjustable desks.

As used herein, the term ‘controller’ and ‘desk controller’ include sit-stand desk electronic control circuitry and interfaces, configured to control movement direction, speed, position, status of the sit-stand desk, and optionally includes any associated electrical motor and drive assemblies adapted to perform the relative movement of the desk surface with respect to the support leg assembly.

As used herein, the terms ‘processor’, ‘processor’, ‘microprocessor’, ‘computing means’ ‘microcontroller’ includes any micro-processing/computing capability, arithmetic, logic, control and communication circuitry, formed from multiple or individual components, integrated or physically distributed, and also includes associated circuitry and interconnections necessary to interface with other components, systems and/or devices.

As used herein, the term ‘handset’ and ‘adapter handset’ includes a user-operable interface, computing and control means, data storage and communications interface.

As used herein, the term ‘pin’ should not be seen to be limiting and should be understood to refer not just to a protruding pin but also includes any component that can form part of an electrical connection, and for example includes a socket, wire, flange, plate, spring, or any other equivalent components.

As used herein, the term ‘pinout fingerprint’ includes a specification of metrics of a multi-pin or contact interface connecting an electrical device or connector, including, but not limited to the pin location, sequence, type, polarity, voltage, physical properties, the functions of transmitted signals and the circuit input/output (I/O) requirements.

As used herein, the term ‘database’ includes data storage, memory databases, local and remote storage, discrete and integrated data storage, on-chip databases and data storage integrated into System on Chip (SoC) devices, microcontrollers and the like.

As used herein, the term ‘operational power’ with respect to electrical power includes the application of sufficient or full power to enable an electrical device, circuit, component or the like to operate unrestricted, and in accordance with the manufacturer's prescribed parameters.

As used herein, the terms ‘parasitic power’ and ‘diagnostic power’ refer to the application of sufficient power to perform diagnostic functions and may be interpreted as interchangeable.

As used herein the term ‘driven’, with reference to the state of an electrical component, refers to the component having an electrical potential (voltage) applied relative to other components, e.g. the voltage being in the form of an output signal or a constant voltage power supply. Axiomatically, the term ‘undriven’, as used herein, refers to the component being a receiving component for an input signal or at a ‘zero’ voltage state.

It will be appreciated that the terms ‘verified, determined, predetermined, redesignated, validated, identified’ and the like are used herein as representations to aide clarity and comprehension and may not necessarily denote individual, explicit, or overt steps or stages in the programming and/or operation of the processor and may be alternatively accomplished in known manor by applicable programming techniques, implementations and/or equivalents.

Some portions of the descriptions in this document are presented in terms of procedures, logic blocks, processing, protocols and other symbolic representations of operations on data bits within a computer memory. These descriptions and representations are the means used by those skilled in the data processing arts to most effectively convey the substance of their work. In the present application, a procedure, logic block, process, function, or the like, is a self-consistent sequence of steps or instructions leading to a desired result. Reference herein will also be made to various computer-implemented “steps” which should be understood to refer to one or more computer-implemented processes, procedures, functions and/or calculations that are capable of accessing, reading, processing, modifying, creating or otherwise manipulating data.

The “steps” of each method are those requiring physical manipulations of physical quantities. Usually, although not necessarily, these quantities take the form of electrical or magnetic signals capable of being stored, transferred, combined, compared, and otherwise manipulated in a computer system. It should be borne in mind, however, that all of these and similar terms are to be associated with the appropriate physical quantities and are merely convenient labels applied to these quantities. Unless specifically stated otherwise as apparent from the following discussions, it is appreciated that throughout the present disclosure, discussions utilizing the terms such as “aborting,” “accepting,” “accessing,” “adding,” “adjusting,” “analyzing,” “applying,” “assembling,” “assigning,” “balancing,” “blocking,” “calculating,” “capturing,” “combining,” “comparing,” “collecting,” “creating,” “debugging,” “defining,” “delivering,” “depicting,” “designating”, “detecting,” “determining,” “displaying,” “establishing,” “executing,” “filtering,” “flipping,” “generating,” “grouping,” “hiding,” “identifying,” “initiating,” “investigating,” “interacting,” “matching,” “modifying,” “monitoring,” “moving,” “outputting,” “performing,” “placing,” “positioning,” “presenting,” “processing,” “programming,” “querying,” “receiving” “removing,” “repeating,” “resuming,” “sampling,” “scanning,” “selecting,” “sending,” “simulating,” “sorting,” “storing,” “subtracting,” “suspending,” “tracking,” “transcoding,” “transforming,” “transferring,” “transforming,” “unblocking,” “using,” “validating,” “verifying,” or the like, refer to the action and processes of a computer system, processor, or similar electronic computing device, that manipulates and transforms data represented as physical (electronic) quantities within the computer system's registers and memories into other data similarly represented as physical quantities within the computer system memories or registers or other such information storage, transmission or display devices.

To aid brevity and clarity, reference herein will also be made to hardware devices in the singular, however, such reference should be interpreted to also include multiple components forming the device and/or multiple devices sharing the function.

To aid brevity and clarity, reference herein will also be made to software in the singular, however, such reference should be interpreted to also include multiple components forming the device and/or multiple devices sharing the function.

Although the present disclosure is described in relation to sit-stand desks, it should be understood that the present disclosure may also be used in other applications, and in different embodiments. Such alternative applications include those characterised by a requirement to provide control (via an adapter handset) to disparate devices with unpredictable or unidentified interface configurations/protocols. In particular, to those where electrical power for the adapter handset is derived from the disparate devices. Other examples are electrically height-adjustable monitor arms and electrically height adjustable hospital beds.

The inventive aspects may be understood from a consideration of the constraints and nature of three primary commercial sales channels; Business to Business (B2B), resellers, and Direct-to-Consumers (DTC), i.e.:
1. B2B: Sit-stand workstation manufacturers, purchasing adapter handsets directly, to both upgrade the functionality of existing stocked models and as an OEM fitment for new products to provide/enhance smart office functionality;
2. Resellers: office fit-out companies, typically tasked with specifying, sourcing and installing (or upgrading) large numbers of workstations per contract (e.g., 1,000-20,000)—often from a single supplier; and
3. DTC: small volume purchases by individual users, small companies and/or organisations, purchasing via DTC sales to replace a customer's existing, less capable sit-stand desk handset or building custom/DIY desks.

In each of these applications, there may be many instances when the specific identity (and associated handset interconnection configuration) of the sit-stand desk being shipped or upgraded/updated is not certain. This uncertainty may arise due to numerous factors, discussed in more details subsequently. Irrespective of the reason, it is clearly practically and commercially desirable for the B2B, reseller and/or DTC customer to fit an adapter handset capable of auto-identification of the desk type and optionally self-configuration to operate same.

It should be noted that any one manufacturer's equipment may use electrical controllers from different OEMs over time in the same models, and often the controllers for these are re-branded or unbranded. This means it is often difficult, if not impossible, to verify what type of controller or manufacturer of controller is being used from external markings. Auto-identification through analysis of the electrical fingerprint may therefore be very important.

According to a first aspect of the present disclosure, there is provided an adapter handset configured to electrically interface with a desk controller of an electrically powered sit-stand desk,
the adapter handset including:
   a multi-pin handset connector, and
   a processor,
the desk controller including:
   a multi-pin desk controller connector
wherein in use, the adapter handset is configured to electrically interface with the desk controller by
   conductive connections between pins of the multi-pin desk controller connector and corresponding pins of the multi-pin handset connector, and
   voltage measurement of the connected pins of the multi-pin handset connector.

It may be possible to determine a pinout fingerprint configuration from voltage measurement of less than all pins of the multi-pin handset connector. However, optionally, the voltage at each connected pin of the multi-pin handset connector is measured.

Optionally, the adapter handset includes a data storage, configured for storage of a plurality of pinout fingerprint configurations.

Optionally, the adapter handset is further configured in use to electrically interface with the desk controller by:
comparison of pinout fingerprint voltages with stored records of predetermined desk controllers.

Optionally, the stored records are stored in a database located in the adapter handset.

Alternatively, the database is located remotely and communicates with the adapter handset via a wireless or a wired connection.

Optionally, the database may be updated with data received, including new or altered desk controller pinout fingerprint configurations.

Optionally, the measurement is conducted periodically, intermittently, or regularly (e.g., every 500 ms).

Optionally, the voltage measurement is controlled by at least one computer program.

Optionally, the sit-stand desk includes at least one:
electrical motor;
height adjusting linear actuator for altering the height of the desk, the actuator coupled to the motor;
electronic desk controller, configured to control the motor to adjust the desk height via the linear actuator;
the desk controller further including the multi-pin desk controller connector.

Optionally, the physical interconnection between the handset connector and the desk controller connector are formed by mating halves of a RJ45, RJ50 connector, or equivalent.

To aid clarity and readability, reference will be made to utilising a 10 pin RJ45 (unless explicitly stated otherwise), though this is purely exemplary and it will be readily understood by one skilled in the art, that alternative connectors may be employed without departing from the scope of the present disclosure, including connectors with differing pin numbers and configurations,

Thus, according to a further aspect, there is provided an electrically powered sit-stand desk including at least one:
electrical motor;
height adjusting linear actuator for altering the height of the desk, the actuator coupled to the motor;
electronic desk controller, configured to control the motor to adjust the desk height via the linear actuator;
the desk controller further including a multi-pin desk controller connector.
   wherein the sit-stand desk further includes an adapter handset configured to electrically interface with the desk controller, the adapter handset including:
a multi-pin handset connector, having a 1^{st} pinout fingerprint corresponding to the desk controller;
at least one processor.

Optionally, the adapter handset includes a data storage, configured for storage of a plurality of pinout fingerprint configurations.

Optionally, in use, operative control of the sit-stand desk by the adapter handset via the handset connector is initiated by:
a conductive connection between at least one pin of the multi-pin desk controller connector and at least one corresponding pin of the multi-pin handset connector;
voltage measurement of each of the at least one pin of the multi-pin desk controller connector, to give a 1^{st} undetermined Desk Controller Connector Pinout Fingerprint (DCCPF);
comparison of the 1^{st} undetermined DCCPF voltages with predetermined DCCPFs, each corresponding with a predetermined desk controller type;
verification of the 1^{st} undetermined DCCPFs' correspondence with a 1^{st} the predetermined DCCPF;
re-configuration of the adapter handset multi-pin handset connector to match the 1^{st} predetermined DCCPF.

Thus, according to a further aspect, the disclosed embodiments may include a method of electrically interfacing an adapter handset with a desk controller of an electrically powered sit-stand desk,
the adapter handset including:
   a multi-pin handset connector,
   at least one processor,
the desk controller including:
   a multi-pin desk controller connector,
wherein the method incudes one or more of the steps of:
   Desk Controller Connector Pinout Fingerprint (DCCPF) identification;
   Adapter Handset Connector Pinout Fingerprint (AHCPF) reconfiguration;
   resolving multiple and/or ambiguous (DCCPF) matches, and monitor desk controller connector for disconnection status.

Optionally, the method is preceded by the step of:
physically interconnecting the handset connector and the desk controller connector.

Optionally, the method further includes the step of:
powering the adapter handset processor via parasitic power extracted from the desk controller connector.

Optionally, the present disclosed embodiments may include a method of electrically interfacing an adapter handset with a desk controller of an electrically powered sit-stand desk,
the adapter handset including:
   a multi-pin handset connector,
   processor,
the desk controller including:
   a multi-pin desk controller connector,
wherein the multi-pin handset connector is connected to the multi-pin desk controller connector and the method incudes the step of:
desk controller connector pinout fingerprint (DCCPF) identification, including,
   configuring each pin of the multi-pin handset connector to an undriven state;
   the processor scanning each pin of the multi-pin handset connector to measure voltage at each corresponding connected pin of the multi-pin desk controller connector;
   repeating the scanning if no voltage is detected at any of the pins;
   recording the voltage at each pin if voltage is detected at any pin, the voltages at each pin stored as a 1^{st} undetermined desk controller connector pinout fingerprint ((DCCPF);
   comparison of the 1^{st} undetermined desk controller connector pinout fingerprint with a stored plurality of predetermined DCCPF;
   wherein comparison outcomes are:
Stage i) if no match is identified with stored predetermined DCCPF, then the 1st undetermined DCCPF is designated as an ‘unidentified’ DCCPF,
Stage ii) matched with a 1^{st} predetermined DCCPF, corresponding to a 1^{st} sit-stand desk.

Optionally, the comparison outcomes further includes:
Stage iii) matched with a 1^{st} and 2^{nd} predetermined DCCPF, corresponding, respectively, to a 1^{st} and 2^{nd} sit-stand desks.

Optionally, the comparison of outcomes is preceded by adding a 20% tolerance to the measured values. Such a tolerance margin may be necessary as there is often an inherent variability in different devices, e.g. due to electrical noise, variability in electronic components, load, or slight changes in circuitry design.

According to another aspect, there is provided a method of electrically interfacing an adapter handset with a desk controller of an electrically powered sit-stand desk,
the adapter handset including:
   a multi-pin handset connector,
   a processor,
the desk controller including:
   a multi-pin desk controller connector,
wherein the adapter handset has an adapter handset connector pinout fingerprint (AHCPF) and the method incudes the steps of:
   powering the adapter handset processor by drawing diagnostic power from the desk controller connector, and
   adapter handset connector pinout fingerprint (AHCPF) reconfiguration, wherein the processor reconfigures the AHCPF to dynamically switch control circuitry, thus re-routing:
      inputs from the desk controller connector to outputs on the processor, and
      outputs from the desk controller connector to inputs on the processor.

Optionally, the adapter handset connector pinout fingerprint (AHCPF) reconfiguration includes drawing operational power from the desk controller connector.

Optionally, the adapter handset re-routes the operational power to the desk controller connector.

Optionally, if the 1^{st} undetermined DCCPF is successfully matched with at least one predetermined DCCPF, the processor reconfigures the pins of the handset connector such that the AHCPF corresponds with a 1^{st} the predetermined DCCPF.

Optionally, the AHCPF reconfiguration further includes replacing the diagnostic or ‘parasitic’ power extracted from the desk controller connector with full power to the circuitry in the adapter handset.

Optionally, the AHCPF reconfiguration further includes routing connections from serial Rx/Tx pins of the desk controller connector to the processor.

Optionally, each pin of the handset connector is reconfigurable as at least one of:
1. a push-pull Universal Asynchronous Receiver-Transmitter (UART);
2. an open collector UART;
3. an open collector Input Output (IO);
4. a bidirectional IO, and/or
5. an Active High Current Source (AHCS).

It will be further apparent that not only are the pins of the adapter handset connector reconfigurable to emulate any OEM handset capabilities, the pins may also be reconfigured to provide custom functionality.

Optionally, each pin of the handset connector is connected via a multiplexer to an Analog to Digital Converter (ADC) in the processor.

Optionally, the processor scanning each pin of the multi-pin desk controller connector, executes the voltage measurements via the ADC.

It will be well understood by one skilled in the art that reconfiguring an electrical interface with the potential to connect outputs to outputs, or power supply to signal outputs generates an appreciable risk of damage, e.g., a ground power supply connected to an output that is trying to drive high, could create a ‘short’ and destroy components.

Optionally, therefore, the adapter handset includes Input voltage protection, and over-current output protection, and the desk controller includes over-current protection.

Optionally, the aforementioned method of adapter handset connector pinout fingerprint (AHCPF) reconfiguration includes:
reconfiguring the handset connector such that the AHCPF corresponds with the matched predetermined DCCPF;
submission of one or more interrogatory communications to the desk controller;
verifying the response validity of the DCCPF match by assessing the handset controller's response validity to validate a communication protocol of the desk controller,
designating the undetermined DCCPF as the matched predetermined DCCPF if the response is determined to be valid, and
redesignating the undetermined DCCPF as an unidentified DCCPF and/or generating a message or alert if the response is determined to be invalid.

Optionally, the adapter handset includes at least one display.

Optionally, a message or other alert is displayed on an adapter handset display if the response is determined to be invalid.

It will be appreciated that the communication protocol may be different for various desk controllers, e.g. some may use a proprietary hexadecimal code protocol, others may use binary or other equivalent protocols.

In one embodiment, if the matched predetermined DCCPF is unsuccessfully validated and the undetermined DCCPF is redesignated as an unidentified DCCPF (and optionally, an ERROR message is displayed on the adapter handset display), the adaptor handset is configured to display one or more queries for a user to perform one or more interactive adaptor handset inputs and/or confirmations of a predetermined test action.

Optionally, the disclosed embodiments may include a method of electrically interfacing an adapter handset with a desk controller of an electrically powered sit-stand desk,
the adapter handset including:
   a multi-pin handset connector,
   a processor,
   data storage, configured for storage of a plurality of pinout fingerprint configurations:
the desk controller including:
   a multi-pin desk controller connector,
wherein the method incudes the step of resolving multiple DCCPF matches, by at least one of:
   each of the multiple DCCPF matches being individually, and successively, used to reconfigure the handset connector such that the AHCPF corresponds with its matched predetermined DCCPF;
   verifying the response validity of each the DCCPF match by submission of one or more interrogatory communications submitted to the desk controller;
   assessing the handset controller's response validity, and if accurate, then designating the undetermined DCCPF as the matched predetermined DCCPF, else repeat the reconfiguration, verification and assessment for next matched DCCPF, and
   if all matched predetermined DCCPFs are unsuccessfully validated, the undetermined DCCPF is redesignated as an unidentified DCCPF.

Optionally, if the undetermined DCCPF is redesignated as an unidentified DCCPF an ‘ERROR’ message or other alert is displayed on an adapter handset display or remote display.

Alternatively, if all matched predetermined (DCCPF) fail validation and the undetermined DCCPF is redesignated as an unidentified DCCPF (and optionally, an ERROR message is displayed on the adapter handset display), the desk user is invited to participate in one or more interactive adaptor handset inputs and/or confirmations of predetermined test actions by the adaptor handset.

Optionally, the disclosed embodiments may include a method of electrically interfacing an adapter handset with a desk controller of an electrically powered sit-stand desk, the adapter handset including:
a multi-pin handset connector,
   processor
   data storage, configured for storage of a plurality of pinout fingerprint configurations:
the desk controller including:
   a multi-pin desk controller connector,
wherein the method incudes the step of:
monitoring the desk controller connector for a disconnection status, by continuously
monitoring voltage on at least one adapter handset connector pin, to detect potential disconnection or malfunction of the adapter handset connector.

It can be seen that the present disclosure may offer significant advantages over the prior art including;
the ability for the adapter handset to act as a universal interface and control unit, capable of operating with a wide range of sit-stand desk types;
the ability to receive OTA (over the air) updates of new pinout fingerprints for new or altered desk controllers and new or altered communication protocols for these and thereby add support for new or altered desk controllers that were unknown at the time the adaptor handset was first built.
a handset that requires no, or minimal additional installation costs, as it can be installed as part of the initial installation.
an installation where the costs of the more advanced adaptor handset can be partially offset from the savings from not requiring a handset to be supplied by the manufacturer.

Reference herein is made to various aspects and embodiments of the present disclosure. For clarity and to aid prolixity every possible combination, iteration or permutation of features, aspects and embodiments are not described explicitly. Thus, it should be appreciated that the disclosure herein includes any combination, iteration, multiple or permutation unless explicitly and specifically excluded.

These and other objects, advantages, purposes and features of the present disclosure will become apparent upon review of the following specification in conjunction with the drawings” into the area.

### BRIEF DESCRIPTION OF DRAWINGS

Further aspects and advantages of the present disclosure will become apparent from the following description which is given by way of example only and with reference to the accompanying drawings in which:

FIG. 1 shows a simplified representation of a sit-stand desk with an adapter handset according to a preferred embodiment of the present disclosure;

FIG. 2 shows a simplified representation of the adapter handset of FIG. 1 with a display;

FIG. 3 shows a schematic system diagram of the adapter handset of FIGS. 1 and 2 in its use connected to a desk controller;

FIG. 4 shows a flow chart of a method of operating the adapter handset of FIGS. 1 to 3;

FIG. 5 shows a flow chart of Step 1 of a Desk controller connector pinout fingerprint (DCCPF) identification;

FIG. 6 shows a flow chart of Step 2 of a Desk controller connector pinout fingerprint (DCCPF) identification; and

FIG. 7 shows a flow chart of Step 3 of a Desk controller connector pinout fingerprint (DCCPF) identification.

### DETAILED DESCRIPTION

Although specific advantages have been enumerated above, various embodiments may include some, none, or all, of the enumerated advantages.

Other technical advantages may become readily apparent to one of ordinary skill in the art after review of the following figures and description.

It should be understood at the outset that, although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described below.

Unless otherwise specifically noted, articles depicted in the drawings are not necessarily drawn to scale.

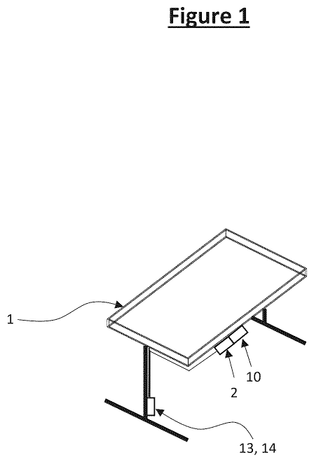

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set. FIG. 1 shows a preferred embodiment of the present disclosure in the form of an electrically powered sit-stand desk (1) with an adapter handset (10) configured to electrically interface with a desk controller (2) of the electrically powered sit-stand desk (1).

A method of electrically interfacing the adapter handset (10) with the desk controller (2) will also be described.

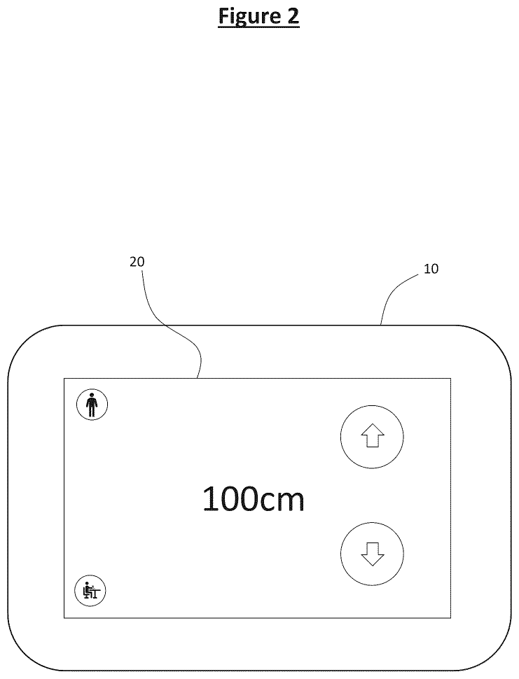

FIG. 2 shows an enlarged view of the adapter handset (10) which has a touch-screen display (20) enabling user control. User control may also be done via the user's phone or computer.

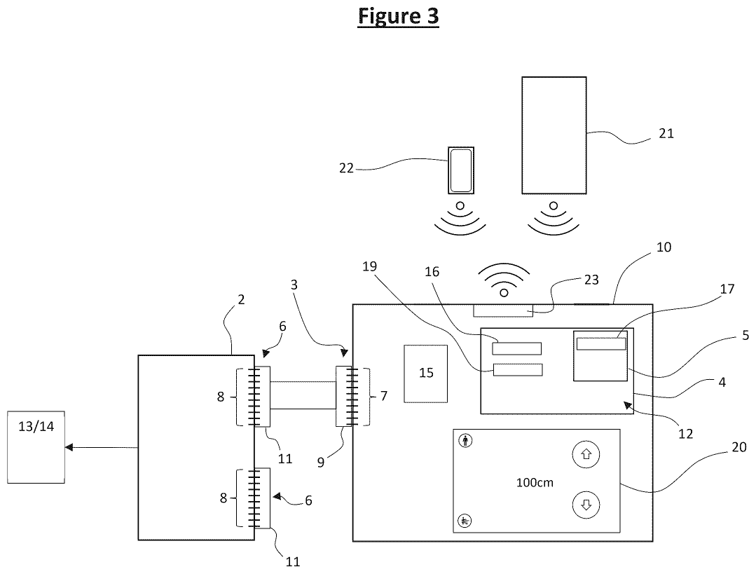

FIG. 3 is a schematic system diagram and shows the adapter handset (10) including a multi-pin handset connector (3), a processor in the form of a microprocessor (4) and data storage (5), configured to store a plurality of pinout fingerprint configurations and desk communication protocols.

The desk controller (2) includes a multi-pin desk controller connector (6). A plurality of adaptor handset connector pins (7) on the adapter handset (10) are configured to connect with corresponding desk controller connector pins (8) via a cable, bus or direct connection.

In the exemplary embodiments described herein, the adaptor handset connector pins (7) are formed as 10 pins of a male RJ45 plug (9), while the desk controller connector pins (8) are formed as 10 pins in a corresponding RJ45 socket (11). It will be readily understood that the position and function of the RJ45 plug and socket (9, 11) may be reversed, and/or other equivalent mating couplings, with differing numbers of pins may also be employed without departing from the scope of the present disclosure. Moreover, the RJ45 plug (9) and socket (11) may also be joined by a length of flexible multi-signal cable (not shown) with further corresponding RJ45 plug and socket.

It will be further appreciated that although an RJ45 connector has 8 pins and an RJ50 connector 10 pins, both have identical dimensions and are physically interchangeable. Thus, by appropriate signal switching, a handset connector (3) with 10 pins may be used to connect to desk controllers (2) with both 8-pin and 10-pin RJ45 and RJ50 connectors without need for a convertor cable. It should be understood that use herein of the term ‘RJ45’ shall be understood to encompass 10 pin RJ50 connectors.

A database is stored in the data storage (5) of the adapter handset (10). In the embodiment shown, the adapter handset (10) utilises a system-on-chip (SoC) (12) integrated circuit to incorporate multiple functions including both the microprocessor (4) and data storage (5). An SoC (12) such as a Nordic Semiconductor® nRF52840 are particularly suited to low-power, mobile applications such as sit-stand desk handsets. It will be readily understood by one in the art that many system components (e.g., radio modems, input/output devices and interfaces, microprocessor and so forth) referred to individually herein, may be physical incorporated directly into the architecture of the SoC (12). The nRF52840 Soc (12) includes 8×GPIOTEs (General Purpose Input Output Task Event) channels, as well as a multiplexer, shift registers, numerous digital and analogue interfaces, and the like, able to be utilised and programmed to configure the individual connecting pins (7) of the handset connector (3) to interface with the corresponding pins (8) of the desk controller connector (6).

Every pin (7) can thus be configured by the SoC (12) to function as a:
Power supply pin
Output signal pin: e.g., sending ‘move desk up’, ‘move desk down’ instructions to the desk controller (2).
Input signal pin: e.g., receiving system state signals such as ‘current desk position’, ‘error codes’ from the desk controller (2).

Thus, each of the ten connector pins (7) need to be switchable in three ways to cover the possible permutations/configurations necessary to interface with any of the separate desk controller (2) types that may be encountered.

It will be appreciated however, that the different functionality provided by SoC (12) described above may also be provided by discrete componentry or a mixture of same e.g., the stored database may be located in the adapter handset, and/or remotely e.g., cloud storage (not shown) and accessible via a wireless or wired connection. The SoC (12) is thus not described in greater detail for the sake of clarity and readability.

As shown in FIG. 1, the sit-stand desk (1) includes an electrical drive motor (13) for effectuating height adjustment of the desktop and desk-hight-adjusting linear actuator (14), coupled to the motor (13). The electronic desk controller (2) is configured to control the motor (13) to adjust desk-height via the linear actuator (14). The desk controller (2) interfaces with external control inputs (e.g., from a user-operated desk handset (not shown) via at least one multi-pin desk controller connector (6), represented in FIG. 3 as a pair of the RJ45 sockets (11). The sit-stand desk (1) may already be equipped with an OEM desk handset (not shown) or supplied absent any form desk handset which consequently be sourced separately by the customer.

As previously discussed, the commercial originating circumstances for a sit-stand desk (1) customer needing to source an adapter handset (10) to replace (or supplement) an OEM desk handset (not shown) fall into three general channels:
A. B2B: Sit-stand workstation manufacturers, purchasing adapter handsets (10) directly, to both upgrade the functionality of existing stocked sit-stand desk (1) models and as the endorsed OEM fitment for new products to provide/enhance smart office functionality;
B. Resellers: office fit-out companies, typically tasked with specifying, sourcing and installing (or upgrading) large numbers of workstations per contract (e.g., 1,000-20,000)—often from a single supplier; and
C. DTC: small volume purchases by individual users, small companies and/or organisations, purchasing via DTC sales to replace a customer's existing, less capable sit-stand desk handset or building custom/DIY desks.

In each of the above, there may be many instances when the specific identity (and associated handset interconnection configuration) of the sit-stand desk (1) being shipped or upgraded/updated is not certain. Irrespective of the reason, it is clearly practically and commercially desirable for the B2B, reseller and/or DTC customer to fit an adapter handset (10) capable of auto-identification of the desk type and self-configuration to operate same.

The process of electrically interfacing with, and providing control of, the sit-stand desk (1) by the adapter handset (10) is initiated by forming a conductive connection between each pin (8) of the desk controller connector (6) with a corresponding pin (7) of the handset connector (3), i.e., by inserting the male RJ45 plug (9) into the female RJ45 socket (11).

As previously referenced, there is no certainty what pinout configuration may be implemented when interfacing with any given desk controller (2), nor even which pins (8) of the desk controller connector (6) are the power pins. Even the potential operating voltage being encountered from different component manufacturer range widely, e.g., from 3 v, 5 v, 9 v, 12 v, 24 v or even 48 v. Consequently, attempting to derive power for the adapter handset (10) from desk controller connector (6) is fraught with uncertainty and potential hazard (e.g., shorting out or otherwise damaging the desk by connecting a driving output on the adapter handset to a desk controller output.

It will be clear that an alternative solution to safely providing electrical power to the adapter handset (10) is simply to provide an independent power source, such as a battery supply (not shown) or via a USB connection to a desktop computer or laptop. However, this adds complexity to the adapter handset (10) itself, and adds the maintenance overhead of monitoring and resupply of spent batteries, reduces shelf/storage lifespan and/or adds reliance on other further devices—e.g. desktop computers.

It is thus still highly desirable to be able to source power for the adapter handset (10) from the desk controller (2) without jeopardising the electrical integrity of the circuitry. However, there is a clearly a self-limiting dynamic that the SoC (12) is restricted in its ability to be preconfigured correctly to safely receive operating power without first receiving at least some initiating electrical power. Thus, the adapter handset (10) incorporates a bootstrapping, parasitic power supply circuitry (15) (incorporating a diode network, an input protected with an overvoltage cut-off, and a voltage regulator) to provide polarity protection, and limited current for the processor and associated circuitry to perform the DCCPF identification and AHCPF reconfiguration. The parasitic power supply circuitry (15) uses the diodes to ensure correct polarity power (available from any pin (8) of the on the desk controller connector (6)) and the voltage regulator restricts the voltage supplied to a level sufficient to initialise the SoC (12) micro-processor, which, in turn provides power to the rest of the adapter handset (10) electronics, which can then power up.

At a general overview level, one preferred embodiment of a method of operative control of the sit-stand desk (1) by the adapter handset (10) via the handset connector (3) includes the general steps of:
making a conductive connection between each pin (8) of the multi-pin RJ45 socket desk controller connector (6) and a corresponding pin (7) of the multi-pin RJ45 plug handset connector (3);
voltage measurement of each pin (8) of the multi-pin desk controller connector (6), to give a 1^{st} undetermined desk controller connector pinout fingerprint (DCCPF) (16);
comparison of the 1^{st} undetermined DCCPF (16) voltages with records in the stored database of predetermined desk controller connector pinout fingerprints (DCCPF) s (17), each corresponding with a predetermined desk controller (2) type, to find any matching predetermined DCCPFs (17);
re-configuration of the adapter handset connector pinout fingerprint (AHCPF) to match one of the found predetermined DCCPFs.

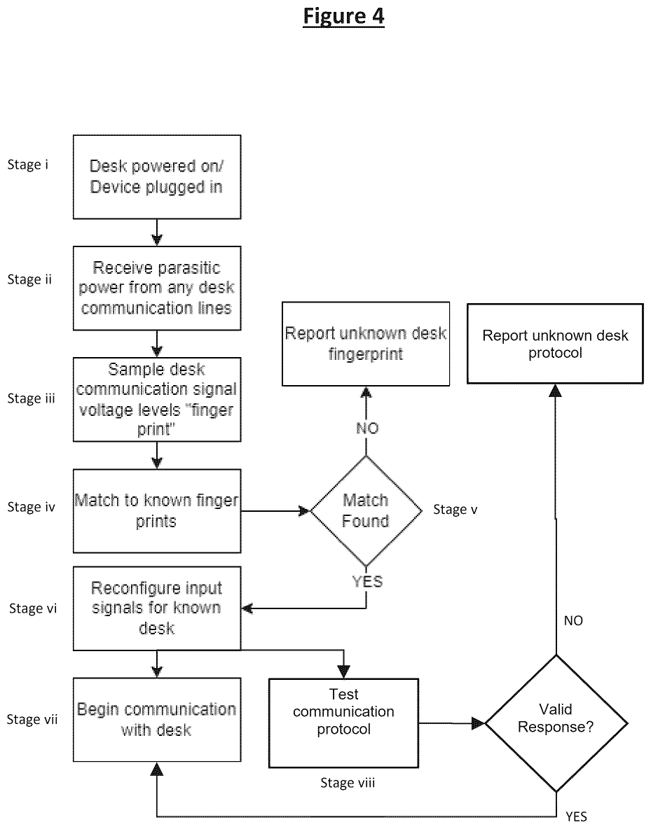

FIG. 4, shows a generalised flow chart of the above-described method, including the steps of;
Stage i) the sit-stand desk (1) is powered on, the handset connector (3) and the desk controller connector (6) are coupled together,
Stage ii) the desk controller (2) provides sufficient power to the handset power supply circuitry via the pins (8) of the desk controller connector (6), to in turn power the SoC (12),
Stage iii) the voltage levels on each pin (8) of the desk controller connector (6) are measured by the SoC (12) to produce an undetermined desk controller connector pinout fingerprint (DCCPF),
Stage iv) the undetermined DCCPF is compared with a database of stored predetermined DCCPFs,
Stage v) if no match is found, the undetermined DCCPF is reclassified as an unidentified DCCPF and an ERROR signal displayed,
Stage vi) if a match is found, the adapter handset connector pinout fingerprint (AHCPF) is reconfigured to correspond to the matched predetermined DCCPF, and
Stage vii) standard communication and operation of the sit-stand desk (1) can commence,
Stage viii) optionally, or preferentially, the handset may perform validation of the communication protocol by interrogating the desk controller 2. The interrogation includes sending predefined query signals, receiving a response and interpreting/measuring the response to determine if the received response matches a predetermined set of validation rules, thereby indicating that the DCCPF was determined correctly in stage vi). If the response is not matched or otherwise not as expected, then this indicates that the desk controller (2) may be a different controller to that matching the determined DCCPF, may be broken or otherwise malfunctioning. The adapter handset is configured to return a corresponding signal indicating there is a potential unknown desk protocol or faulty desk controller, i.e. “Report unknown desk protocol”. This enables operators to investigate further to determine the source of the mismatch.
Stage viii) is useful in determining if two different desk controller (2) types have fingerprints that are the same or sufficiently similar that they are considered a match but have different signal protocols that mean they are not interoperable.

In more detail, the above method of electrically interfacing an adapter handset (10) with a desk controller (2) of an electrically powered sit-stand desk (1), further incudes the steps of:
desk controller connector pinout fingerprint DCCPF (16) identification;
adapter handset connector pinout fingerprint AHCPF (18) reconfiguration;
resolving multiple and/or ambiguous DCCPF (17) matches, and monitor desk controller connector for disconnection status.

Considering each step individually;

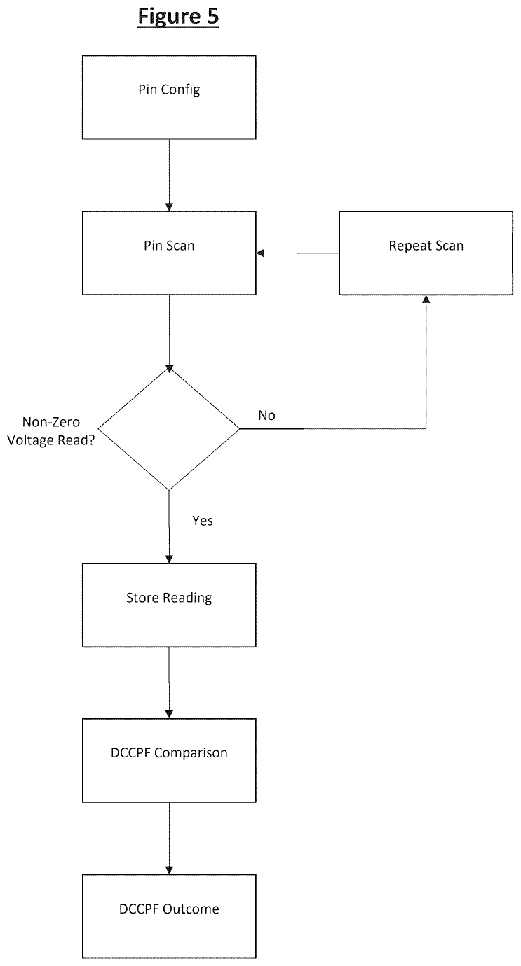

Step 1: Desk controller connector pinout fingerprint (DCCPF) (16) identification, is represented by FIG. 5.

After the adapter handset (10) is receives sufficient electrical power (either parasitically from the desk controller (2) or independently from batteries or a USB PC supply) to operate the SoC (12) microprocessor, an identification of the DCCPF is performed by:
configuring each pin (7) of the multi-pin handset connector (3) as an undriven state;
the SoC microprocessor (12) scanning each pin (7) of the desk controller connector (6) to measure voltage;
if no voltage is detected by the SoC (12), the scanning is repeated;
Store Reading: upon detection of any voltage on any pin (7), each pin (7) and corresponding voltage is recorded and stored in the data storage as a 1st undetermined DCCPF (16);
DCCPF Comparison: performing a comparison of between the 1^{st} undetermined DCCPF (16) and a stored plurality of predetermined DCCPF (17), resulting in one of three comparison outcomes, namely:
   i. no match is identified with the stored predetermined DCCPF, and thus the 1^{st} undetermined DCCPF is designated as an unidentified DCCPF (19), and an ‘ERROR’ message displayed on the adapter handset display (20);
   ii. a match with a single 1^{st} predetermined DCCPF, corresponding to a 1st desk controller (2) and associated sit-stand desk (2) type;
   iii. a match with both a 1^{st} and 2^{nd} (or more) predetermined (DCCPF), corresponding, respectively, to a 1^{st} and 2^{nd} desk controllers (2) and associated sit-stand desk (1) types.

Step 2. adapter handset connector pinout fingerprint (AHCPF) reconfiguration.

In broad terms, in step 2., the SoC micro-processor (4, 12) dynamically switches control circuitry using FETs gates to re-route;
power to the main circuits;
inputs from the controller connector (6) to outputs on the SoC micro-processor (4,12), and
outputs from the controller connector (6) to inputs on the SoC micro-processor (4,12).

Reconfiguration of the AHCPF (18) to correspond to a predetermined DCCPF (17):
replaces a parasitic boot-up power connection (if used) with full power;
connects serial Rx/Tx pins (7, 8) to the SoC CPU (4, 12) to enable serial communication with the desk controller (2), and
pulls high or low voltage of any additional control pins that require this (e.g., for some desk controllers (2) instead of a serial message the desk controller (2) uses a push/pull signal to control the desk).

This reconfiguration of the adapter handset connector pinout fingerprint (AHCPF) (18) includes a total of 60 outputs (i.e. 10 pins, each with 6 potential outputs), including x1 analog input to read the pin (7) voltages (as in step 1), a General Purpose I/O pin (7) for read/write (if the interface pin (7) is an Rx or Tx serial interface), and x6 different outputs for the remaining pins (7) i.e. there is effectively a 6-bit ‘word’ needed to define and activate on each of nine interface types, detailed below.

Table 1. shown below details the 9 different interface types to reconfigure each pin (7) to safely and effectively operate current (and future) predetermined DCCPF (17) and their associated desk controller (2) types.

TABLE 1

| | Desk | Adapter | | |
|---|---|---|---|---|
| | controller | handset | | |
| Type | (2) | (10) | Description | Comments |
| 1 | output | input | +positive power from | active high |
| | power | power | desk controller (2) | current source |
| 2 | output | input | −negative power from | electrical ground |
| | power | power | desk controller (2) | |
| 3 | input/ | Input/ | dual RX/TX serial | |
| | output | output | communication for | |
| | | | desk controller (2) | |
| 4 | input | output | RX serial on desk | push-pull UART |
| | | | controller (2) | |
| 5 | output | input | TX serial on desk | open collector |
| | | | controller (2) | UART |
| 6 | input | output | Input to desk | May be pulled low |
| | | | controller (2) | via a current |
| | | | (GPIO-pull low) | limiting resister to |
| | | | | communicate with |
| | | | | the desk controller |
| | | | | (2) |
| 7 | input | output | Input to desk controller | |
| | | | (2) (GPIO-pull high | |
| | | | strong) | |
| 8 | input | output | Input to desk controller | |
| | | | (2) (GPIO-pull high | |
| | | | weak) | |
| 9 | N/A | N/A | Not connected | can be pull up and |
| | | | | pull down. |

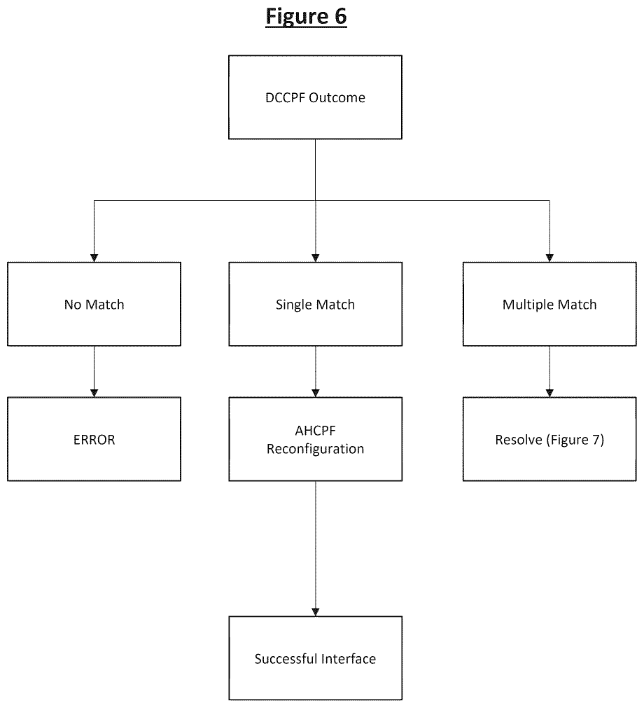

Thus, the three outcomes of step 1. (i.e., resulting from the comparison between the 1st undetermined DCCPF (16) and a stored plurality of predetermined DCCPF (17)), are implemented in step 2. as follows and as represented in FIG. 6:
if no match is identified with the stored predetermined DCCPF, the 1st undetermined DCCPF is designated as an unidentified DCCPF (19), and an ‘ERROR’ message displayed on the adapter handset display (20) and no reconfiguration of the AHCPF is executed;
if the 1^{st} undetermined DCCPF (16) is successfully matched with a 1st predetermined DCCPF (17), the Soc (12) reconfigures the 10 pins (7) of handset connector (3) (i.e., the AHCPF (18)) to corresponded with the 1^{st} predetermined DCCPF (17).
if matching the 1^{st} undetermined DCCPF (16) with the predetermined DCCPF (17) produces an ambiguous result, e.g. a match with both a 1^{st} and 2nd predetermined DCCPF (17)), the ambiguity is addressed by strep 3.

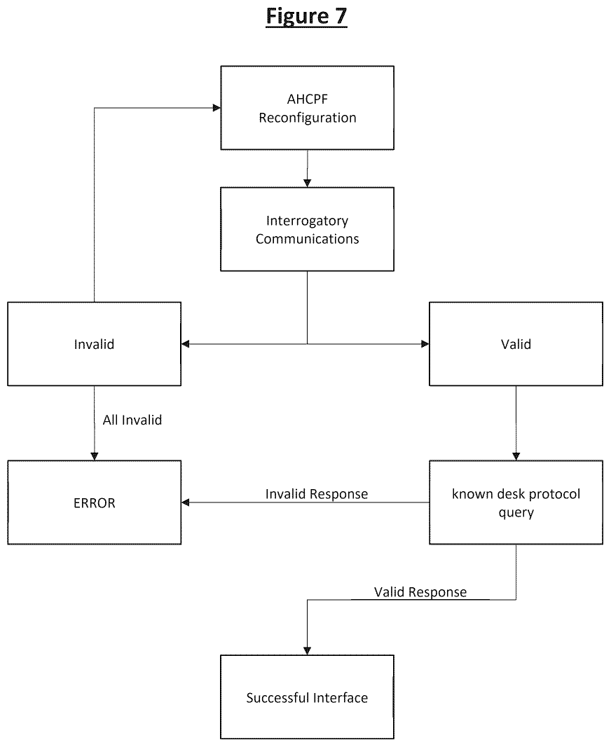

Step 3. resolving multiple and/or ambiguous (DCCPF) matches is shown in FIG. 7.

Firstly, the same process is performed from step 2 (as if a successful match was recorded with a single) is performed, i.e., Soc (12) reconfigures the 10 pins (7) of handset connector (3) (i.e., the AHCPF (18)) to corresponded with the 1^{st} predetermined DCCPF (17).

Secondly, one or more interrogatory communications are undertaken with the desk controller (2) and the response validity is assessed. As an example, a desk-height query is communicated to the desk controller (2) using the correct communication protocol for a sit-stand desk (1) with a 1^{st} predetermined DCCPF, and the response is assessed for validity.

Thirdly;
if the response(s) is/are valid, the sit-stand desk (1) and desk controller (2) are verified as being confirmed as the type corresponding with 1^{st} predetermined DCCPF and a successful interfacing is complete;
if the response(s) is/are invalid, or otherwise unexpected, the process is repeated for each matched predetermined DCCPF (17), e.g., with Soc (12) reconfigures the handset connector (3) so the AHCPF (18) corresponds with the 2nd predetermined DCCPF (17) and so forth;
if all matched predetermined (DCCPF) (17) are unsuccessfully validated, then an ERROR message is displayed on the adapter handset display (20) and the undetermined DCCPF (16) is redesignated as an unidentified DCCPF (19).

Finally, the SoC (12) sends a query according to a known desk protocol of a predefined desk type and checks if an expected behavior or communication signal is received in response. For example, a query for desk height may be made and the signal returned is processed to check if it is a valid desk height response.

Step 4. monitoring the desk controller connector (6) for disconnection status.

The handset connector (3) continuously monitors voltage (e.g. every 500 ms) on the handset connector pins (7) (optionally, only monitoring one or more selected pins instead of all pins) to detect if the desk controller (2) has been disconnected or ceased functioning.

It will be understood that the display (20) is also able to display a variety of status and activity information, in addition to an ERROR message indicating an undetermined DCCPF (19). A user (not shown) is able to interface with the adapter handset (10) via the display (20) and also by a PC/laptop (21) or smartphone (22) or other computing device via sensors and communication circuitry (23) incorporated in the adapter handset (10).

A SoC (12) such as the Nordic Semiconductor® nRF52840 is equipped with numerous external communication capabilities configured to use numerous protocols such as Bluetooth Low Energy, Bluetooth mesh, Thread, Zigbee, ANT, 2.4 GHZ, IEEE 802.15.4 and the like, collectively represented by sensors and communication circuitry (23). This enables OTA firmware updates, functionality upgrades and updates to the library of predetermined DCCPFs (17) in the data storage (5).

It should be understood that there exist implementations of other variations and modifications of the present disclosure and its various aspects, as may be readily apparent to those of ordinary skill in the art, and that the present disclosure is not limited by the specific embodiments described herein. Features and embodiments described above may be combined with and without each other. It is therefore contemplated to cover any and all modifications, variations, combinations or equivalents that fall within the scope of the basic underlying principals disclosed and claimed herein.

Changes and modification in the specifically described examples can be carried out without departing from the principles of the present disclosure which is intended to be limited only by the scope of the appended claims as interpreted according to the principles of patent law including the doctrine of equivalents.

1. An adapter handset configured to electrically interface with a desk controller of an electrically powered sit-stand desk, wherein the desk controller includes a multi-pin desk controller connector, said adapter handset comprising:
a multi-pin handset connector; and
a processor;
wherein in use, said adapter handset is configured to electrically interface with the desk controller via:
conductive connections between pins of the multi-pin desk controller connector and corresponding pins of said multi-pin handset connector, and
voltage measurement of at least two of the connected pins of the multi-pin desk controller connector.

2. The adapter handset as claimed in claim 1, further configured to:
measure voltage of the at least two connected pins of the multi-pin desk controller connector, to give a 1^{st} undetermined Desk Controller Connector Pinout Fingerprint (DCCPF);
compare 1 st undetermined DCCPF voltages with predetermined DCCPFs, each corresponding with a predetermined desk controller type;
match the 1^{st} undetermined DCCPF with at least one of the predetermined DCCPFs; and
re-configure said multi-pin handset connector such that an Adapter Handset Connector Pinout Fingerprint (AHCPF) matches the at least one predetermined DCCPFs.

3. The adapter handset as claimed in claim 1, wherein each of the pins of said multi-pin handset connector is reconfigurable as at least one of:
a push-pull Universal Asynchronous Receiver-Transmitter (UART);
an open collector UART;
an open collector Input Output (IO);
a bidirectional IO; and/or
an Active High Current Source (AHCS).

4. The adapter handset as claimed in claim 1, wherein each of the pins of said multi-pin handset connector is connected via a multiplexer to an Analog to Digital Converter (ADC) in said processor.

5. (canceled)

6. The adapter handset as claimed in claim 1 further in combination with said desk controller, said adapter handset comprising Input voltage protection and over-current output protection, and said desk controller comprising over-current protection.

7. (canceled)

8. The adapter handset as claimed in claim 1, further configured to electrically interface with the desk controller by comparison of pinout fingerprint voltages with stored records of predetermined desk controllers.

9. (canceled)

10. The adapter handset as claimed in claim 1, further configured to perform voltage measurement for all of the pins of the multi-pin desk controller connector.

11. (canceled)

12. The adapter handset as claimed in claim 1, further configured to perform:
Desk Controller Connector Pinout Fingerprint (DCCPF) identification; and
Adapter Handset Connector Pinout Fingerprint (AHCPF) reconfiguration.

13. The adapter handset as claimed in claim 12, wherein to perform the AHCPF reconfiguration, said processor is configured to reconfigure an AHCPF of said adapter handset to switch control circuitry and re-route:
inputs from the multi-pin desk controller connector to outputs on said processor, and
outputs from the multi-pin desk controller connector to inputs on said processor.

14. The adapter handset as claimed in claim 12, wherein to perform the AHCPF reconfiguration, said adapter handset is configured to:
reconfigure said multi-pin handset connector such that the AHCPF corresponds with a matched predetermined DCCPF.

15. The adapter handset as claimed in claim 13, wherein to perform the AHCPF reconfiguration, said adapter handset is configured to:
submit one or more interrogatory communications to the desk controller; and
verify a response validity of a DCCPF match by assessing a handset controller's response validity to validate a communication protocol of the desk controller.

16. The adapter handset as claimed in claim 15, wherein said processor is configured to resolve multiple DCCPF matches by:
AHCPF reconfiguration such that the AHCPF corresponds with at least one of the DCCPF matches,
verification of the response validity of the at least one DCCPF matches by submission of one or more interrogatory communications submitted to the desk controller, and
assessment of a handset controller's response validity.

17. The adapter handset as claimed in claim 16, further configured to resolve the multiple DCCPF matches further by:
repeating reconfiguration, verification and assessment for a next matched DCCPF if the assessment is deemed valid, or
generating an error if all matched predetermined DCCPFs are unsuccessfully validated, or
requesting a user to perform one or more interactions, inputs and/or confirmations of predetermined test actions if all matched predetermined DCCPFs fail the validation and an undetermined DCCPF is not identified.

18. The adapter handset as claimed in claim 1, configured to perform monitoring of the multi-pin desk controller connector for a disconnection status.

19. The adapter handset as claimed in claim 1, further including circuitry configured to receive power, prior to an AHCPF reconfiguration, from any of the pins of the multi-pin desk controller connector and provide power to said processor.

20. An electrically powered sit-stand desk comprising said adapter handset of claim 1 and including at least one:
electrical motor;
height adjusting linear actuator for altering the height of the desk, said linear actuator coupled to said motor;
electronic desk controller, configured to control said motor to adjust the desk height via said linear actuator;
said desk controller further including a multi-pin desk controller connector.

21. A method of electrically interfacing an adapter handset with a desk controller of an electrically powered sit-stand desk, the adapter handset including:
a multi-pin handset connector, and
at least one processor,
the desk controller including:
a multi-pin desk controller connector,
wherein the adapter handset is configured to electrically interface with the desk controller via conductive connections between pins of the multi-pin desk controller connector and corresponding pins of the multi-pin handset connector, and
said method comprising performing a voltage measurement of at least two of connected the pins of the multi-pin desk controller connector, wherein said performing the voltage measurement is used to provide a 1^{st} undetermined Desk Controller Connector Pinout Fingerprint (DCCPF).

22. The method of claim 21, further comprising performing a Desk Controller Connector Pinout Fingerprint (DCCPF) identification, including:
comparing the 1^{st} undetermined DCCPF with predetermined DCCPFs, each corresponding with a predetermined desk controller type, to find any predetermined DCCPFs that match the 1^{st} undetermined DCCPF.

23. The method of claim 22, wherein said performing the DCCPF identification further comprises:
configuring each pin of the multi-pin handset connector to an undriven state;
scanning, by the processor, each pin of the multi-pin handset connector to measure voltage at each corresponding connected pin of the multi-pin desk controller connector;
repeating said scanning if no voltage is detected at any of the pins;
recording the voltage at each of the pins if voltage is detected at any of the pins, the voltages at each of the pins stored as a 1^{st} undetermined DCCPF; and
comparing the 1^{st} undetermined DCCPF with a stored plurality of predetermined DCCPFs to produce comparison outcomes;
wherein the comparison outcomes include:
no match, where there is no matched predetermined DCCPF, and
matched, where there is a match with a 1^{st} predetermined DCCPF, corresponding to a 1^{st} sit-stand desk.

24. The method of claim 23, wherein the comparison outcomes further include:
multiple matches, where the 1^{st} undetermined DCCPF is matched with multiple predetermined DCCPFs.

25-32. (canceled)
